(19) United States
(12) Patent Application Publication
(10) Pub. No.: US 2006/0151857 A1
(43) Pub. Date: Jul. 13, 2006

(54) Thermoadhesive multi-layer film

(76) Inventor: Daniela Gasparoni, Vicenza (IT)

Correspondence Address: RADER, FISHMAN & GRAUER PLLC, 39533 WOODWARD AVENUE, SUITE 140, BLOOMFIELD HILLS, MI, 48304-0610, US

(21) Appl. No.: 11/172,261

(22) Filed: Jun. 30, 2005

(30) Foreign Application Priority Data
Jan. 11, 2005 (WO) PCT/EP05/00158

(51) Int. Cl. H01L 23/58

(52) U.S. Cl. 257/635

(57) ABSTRACT

A thermoadhesive multi-layer film is described having at least four layers. The first and second layers are formed from a paper or a plastic film providing a support or “carrier.” The third layer is a colored film layer formed from at least one polymer-based material and is able to “float” on the support on which it is printed without sinking during the application to the support. The fourth layer is a thermo-softening film formed from at least one polymer-based material adapted to melt on a destination material and fixing a decoration onto the support.

### CROSS-REFERENCE To RELATED APPLICATIONS

This application claims the benefit of PCT Application Ser. No. PCT/EP2005/000158 filed Jan. 11, 2005, which is hereby incorporated by reference in its entirety.

### TECHNICAL FIELD

The embodiment of the invention described herein is generally directed to multi-layer film.

### BACKGROUND

There are currently multi-layer films that are suitable for undergoing computerized cutting using a plotter and thermo-resin printing. Using computerized design programs, multi-layer films are subjected to computerized cutting using a plotter to obtain a “profile” or pattern required for a decoration.

Alternatively, films may be subjected to a digital printing such as thermo-resin printing and inkjet or CLC laser processes. In addition, films are subsequently cut into parts using an electronic processor (plotter). In both cases the films, suitably cut, are transferred onto the destination fabric, through a hot process.

Such a process is used to apply writing, drawings, company logos and the like onto items of clothing be they sports clothes or otherwise, such as T-shirts, overalls, shorts and work clothes. In other words, these films are used to personalize items of clothing and other items, for example: sports bags, umbrellas, and the like.

Typical multi-layer films are made up of the following layers: 1) a first support layer, generally defined as a “carrier”, made from paper, plastic film, or polyester; 2) a second layer of colored polymeric film, generally consisting of polyvinyl chloride or polyurethane or other suitable mixtures, always with the purpose of constituting the visible decoration to be applied to the destination item; 3) a third and final layer of thermo-softening adhesive film, which can be made from polyester, polyamide resin, polyurethane resin, or furthermore with a mixture of these components, based upon the particular characteristics of the fabrics on which the multi-layer film is to be applied.

In particular, Italian patent application no. V194A000066 describes a process able to give a particular roughness to the first layer of plastic support film (the carrier), which can visibly give rise to an “opaque” effect and to a tactile effect similar to that of a “peach”. Alternatively, the first support layer can have a further adhesive layer at the contact surface with the polymeric film; of course, such a support layer can also not have special processing.

In the last few years, the uses of fabrics or similar materials equipped with substantial characteristics of elasticity have become widespread. As an example, there are the materials commercialized with the registered trademarks Lycra™, Spandex™ and Elastine™. These materials are personalized through the heat transfer process described previously. Unfortunately, the decoration, subjected to stretching following tension applied to the material itself, permanently deforms, with the consequent formation of creases, folds and other surface defects. Indeed, the decoration may detach from the material and, in any case, the aforementioned decoration is unable to ensure the aesthetic purpose of distinctive character for which it is intended.

### SUMMARY

A thermoadhesive multi-layer film is described having at least four layers. The first and second layers include a paper or a plastic film providing a support or “carrier.” The third layer is a colored film layer formed from at least one polymer-based material and is able to “float” on the support on which it is printed without sinking during the application to the support. The fourth layer is a thermo-softening film formed from at least one polymer-based material adapted to melt on a destination material and fixing a decoration onto the support.

### BRIEF DESCRIPTION OF THE DRAWINGS

The features and inventive aspects of the present invention will become more apparent upon reading the following detailed description, claims, and drawings, of which the following is a brief description:

FIG. 1 is an exploded cross-sectional view of a thermoadhesive multi-layer film according to one embodiment.

### DETAILED DESCRIPTION

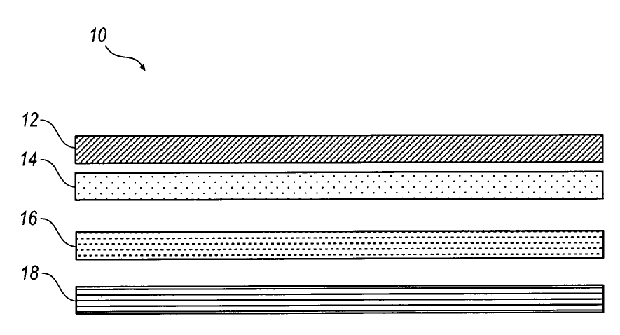

Referring now to FIG. 1, an exemplary embodiment of a multi-layer film 10 is shown in detail. Although the drawing represents the embodiment, the drawing is not necessarily to scale and certain features may be exaggerated to better illustrate and explain an innovative aspect of an embodiment. Further, the embodiment described herein is not intended to be exhaustive or otherwise limit or restrict the invention to the precise form and configuration shown in the drawing and disclosed in the following detailed description.

The multi-layer film 10 illustrated in FIG. 1 provides a number of benefits including effective hot transfer onto an elasticized material, as well as easy removal of the excess material after computerized cutting. Specifically, upon transfer onto a destination material (not shown), the multi-layer film 10 is capable of deforming and being restored into its original form after the multi-layer film 10 is stretched. Any breaking of decoration is avoided after the material has been subjected to elastic deformation. The multi-layer film 10 prevents undesirable flaws in the decoration including creases, bubbles, folds, particle detachments and the like while allowing the multi-layer film to return to its original shape after elastic deformation. There is no interference between the modulus of elasticity of the material and the modulus of elasticity of the multi-layer film 10. Furthermore, easier removal of excess material after a cutting operation in a “final-removal” step is provided. The multi-layer film 10 also provides a “coating” for the material onto which it is applied. The term coating includes the ability of the multi-layer film 10 to keep it coloration unaltered, irrespective of the color of the destination material onto which it is applied.

The aforementioned benefits are obtained by providing the multi-layer film 10 having at least four layers including a first support layer 12, a second support layer 14, a colored film layer 16, and a thermo-softening film layer 18.

The first support layer 12 or “first carrier” is formed from a paper or a polyester plastic film, made suitably sticky or alternatively treated to give it particular roughness. The second support layer 14 or “second carrier” is formed from paper or plastic film suitable for acting as a support formed from one of a polyester, a polythene or a polypropylene material. The colored film layer 16 formed from one or more polymer-based materials is able to “float” on the support layers 12, 14 without sinking during the application of the writing to the support layers 12, 14. The thermo-softening film layer 18 is also formed from one or more polymer-based materials intended to melt onto the destination material, fixing the decoration to the aforementioned support layers 12, 14.

In one embodiment, the colored film layer 16 is formed from one or more polymer-based materials having kofler/hot melting points (ANSI/ASTM D3451-76) greater than 160° Celsius and comprising more than 50 percent (50%) of polymer-based materials. The colored film layer 16 is able to “float” on the destination material without sinking during the application of the decoration to the aforementioned material. Moreover, the colored film layer may be able to deform mechanically, both longitudinally and transversally, according to one embodiment having the properties in standard ISO 527-3/2/200.

ISO standard 527-3/2/200 includes the following properties: a) elongation at break is greater than 600%, both in the longitudinal direction, and in the transversal direction; b) modulus of elasticity at 100% is less than 9 MPA, both in the longitudinal direction, and in the transversal direction; and c) modulus of elasticity at 300% is less than 20 MPA, both in the longitudinal direction, and in the transversal direction.

In yet another embodiment, the colored film layer 16 is formed from a base of polymers of greater than 50% selected from a group comprising acrylic resins, polyurethane resins (PU), co-polyester resins (TPE-E), co-polyamide resins (TPE-PA) and/or their mixtures.

The thermo-softening film layer 18 may be formed from one or more materials in a polymer phase and in one embodiment greater than 50% thermoplastic having kofler/hot melting points (ANSI/ASTM D3451-76) less than 140° Celsius. The thermo-softening film layer 18 may be subjected to suitable pressure and temperature conditions for a certain time and melting onto the destination material beneath fixing the writing to the aforementioned destination material.

It is possible to ensure that the combination of the colored film layer 16 and the thermo-softening film layer 18 may be obtained through co-extrusion in flat or blown film, through spreading, through calendering or through lamination of many films.

An embodiment of the thermo-softening film layer is formed from a base of polymers of greater than 50% selected from a group comprising acrylic resins, polyurethane resins (PU), co-polyester resins (TPE-E), co-polyamide resins (TPE-PA) and/or their mixtures.

In particular, the multi-layer film 10 passes the ASTM D412 standard through an “elongation set”; such standards foresee the application of strains on the writing for a period of five minutes.

The ASTM D412 standard includes: a) the elastic retention (or permanent deformation) after elongation at 100% must be less than or equal to 20%, both in the longitudinal direction, and in the transversal direction; b) elastic retention (or permanent deformation) after elongation at 200% must be less than or equal to 45%, both in the longitudinal direction, and in the transversal direction.

One embodiment of the multi-layer film 10 includes the following thicknesses: the first support layer 12 being a thickness of generally 70 μm; the second support layer 14 being a thickness of generally 20 μm; the colored film layer 16 being a thickness of generally 60 μm; and the thermo-softening film layer 18 being a thickness of generally 60 μm.

The preceding description has been presented only to illustrate and describe an exemplary embodiment of the method and system of the present invention. It is not intended to be exhaustive or to limit the invention to any precise form disclosed. It will be understood by those skilled in the art that various changes may be made and equivalents may be substituted for elements thereof without departing from the scope of the invention. In addition, many modifications may be made to adapt a particular situation or material to the teachings of the invention without departing from the essential scope. Therefore, it is intended that the invention not be limited to the particular embodiment disclosed as the best mode contemplated for carrying out this invention, but that the invention will include all embodiments falling within the scope of the claims. The invention may be practiced otherwise than is specifically explained and illustrated without departing from its spirit or scope. The scope of the invention is limited solely by the following claims.

What is claimed is:

1. A thermoadhesive multi-layer film comprising:
a first support layer;
a second support layer disposed on said first support layer;
a colored film layer disposed on said second support layer having a decoration; and
a thermo-softening film layer disposed on said colored film layer.

2. The multi-layer film of claim 1, wherein said first support layer is made from a paper or a polyester plastic film, said first support layer having a sticky or rough surface.

3. The multi-layer film of claim 1, wherein said second support layer is made from paper, plastic film, polyurethane, or polyvinyl chloride.

4. The multi-layer film of claim 1, wherein said colored film layer is made from at least one polymer-based material.

5. The multi-layer film of claim 1, wherein said first support layer and said second support layer form a support.

6. The multi-layer film of claim 5, wherein said thermo-softening film layer is made from at least one polymer-based material adapted to melt onto a destination material fixing said decoration onto said support.

7. The multi-layer film of claim 1, wherein said colored film layer is formed from at least one polymer-based material having a melting point greater than 160° Celsius.

8. The multi-layer film of claim 7, wherein said colored film layer includes more than 50 percent (50%) of said at least one polymer-based material.

9. The multi-layer film of claim 1, wherein said colored film layer is able to float on a destination material without sinking into said destination material during application of said decoration.

10. The multi-layer film of claim 1, wherein said colored film layer conforms to ISO standard 527-3/2/200.

11. The multi-layer film of claim 1, wherein said colored film layer includes a polymer material selected from a group comprising acrylic resins, polyurethane resins (PU), co-polyester resins (TPE-E), co-polyamide resins (TPE-PA), or a combination of said group.

12. The multi-layer film of claim 1, wherein said thermo-softening film layer is formed from at least one polymer-based material having a melting point less than 140° Celsius.

13. The multi-layer film of claim 12, wherein said thermo-softening film layer includes more than 50 percent (50%) of said at least one polymer-based material.

14. The multi-layer film of claim 1, wherein said thermo-softening film layer conforms to ISO standard 527-3/2/200.

15. The multi-layer film of claim 1, wherein a combination of said thermo-softening film layer and said colored film layer is obtained through co-extrusion in a flat or a blown film, through spreading, through calendaring, or through lamination of films.
